(19) United States
(12) Patent Application Publication
(10) Pub. No.: US 2023/0216470 A1
(43) Pub. Date: Jul. 6, 2023

(54) BULK-ACOUSTIC WAVE RESONATOR

(71) Applicant: SAMSUNG ELECTRO-MECHANICS CO., LTD., Suwon-si (KR)

(72) Inventors: Won HAN, Suwon-si (KR); Hwa Sun LEE, Suwon-si (KR); Jeong Hoon RYOU, Suwon-si (KR); Moon Chul LEE, Suwon-si (KR); Tae Yoon KIM, Suwon-si (KR); Sang Kee YOON, Suwon-si (KR); Yong Suk KIM, Suwon-si (KR); Joung Hun KIM, Suwon-si (KR); Sung Jun LEE, Suwon-si (KR); Sung Joon PARK, Suwon-si (KR)

(73) Assignee: SAMSUNG ELECTRO-MECHANICS CO., LTD., Suwon-si (KR)

(21) Appl. No.: 17/824,145

(22) Filed: May 25, 2022

(30) Foreign Application Priority Data
Dec. 31, 2021 (KR) 10-2021-0194411

(51) Int. Cl. H03H 9/02; H03H 9/17

(52) U.S. Cl. CPC H03H 9/0211; H03H 9/173; H03H 9/02102

(57) ABSTRACT

A bulk acoustic wave resonator includes a substrate; a central portion including a first portion of a first electrode, a first portion of a piezoelectric layer, and a first portion of a second electrode laminated in order on the substrate; and a reflective region disposed laterally of the central portion and including a second portion of the first electrode, an insertion layer, a second portion of the piezoelectric layer, and a second portion of the second electrode. A side surface of the insertion layer adjacent to the central portion has an inclined surface, the first portion of the second electrode and the second portion of the second electrode are coplanar, and an end of the second electrode overlaps the inclined surface of the insertion layer in the reflective region.

### CROSS-REFERENCE TO RELATED APPLICATIONS

This application claims the benefit under 35 USC 119(a) of priority to Korean Patent Application No. 10-2021-0194411 filed on Dec. 31, 2021 in the Korean Intellectual Property Office, the entire disclosure of which is incorporated herein by references for all purposes.

### BACKGROUND

### 1. Field

The following description relates to a bulk-acoustic wave resonator.

### 2. Description of Background

In accordance with the trend for the miniaturization of wireless communications devices, there has been increasing demand for miniaturization of high-frequency components, and for example, a bulk acoustic wave resonator (BAW) type filter based on the technique of manufacturing a semiconductor thin film wafer has been used.

A bulk acoustic wave resonator (BAW) may refer to a thin film device configured as a filter, which may generate resonance using piezoelectric properties by depositing a piezoelectric dielectric material on a silicon wafer, a semiconductor substrate.

Recently, interest in 5G communications technology has increased, and development of an acoustic resonator technology which may be implemented in a candidate band has been actively conducted. Also, research into various structural shapes and functions to improve properties and performance of a bulk-acoustic wave resonator has been conducted, and research on a method of manufacturing the same has also been continuously conducted.

### SUMMARY

This Summary is provided to introduce a selection of concepts in simplified form that are further described below in the Detailed Description. This Summary is not intended to identify key features or essential features of the claimed subject matter, nor is it intended to be used as an aid in determining the scope of the claimed subject matter.

In one general aspect, a bulk acoustic wave resonator includes: a substrate; a central portion including a first portion of a first electrode, a first portion of a piezoelectric layer, and a first portion of a second electrode laminated in order on the substrate; and a reflective region disposed laterally of the central portion and including a second portion of the first electrode, an insertion layer, a second portion of the piezoelectric layer, and a second portion of the second electrode. A side surface of the insertion layer adjacent to the central portion has an inclined surface, the first portion of the second electrode and the second portion of the second electrode are coplanar, and an end of the second electrode overlaps the inclined surface of the insertion layer in the reflective region.

A combined thickness of the second portion of the first electrode, the insertion layer, the second portion of the piezoelectric layer, and the second portion of the second electrode disposed in the reflective region may be equal to a combined thickness of the first portion of the first electrode, the first portion of the piezoelectric layer, and the first portion of the second electrode disposed in the central portion.

The first portion of the piezoelectric layer may include a piezoelectric portion disposed in the central portion and the second portion of the piezoelectric layer may include an inclined portion disposed on the inclined surface of the insertion layer, and the inclined portion may have a thickness decreasing in a direction away from the piezoelectric portion.

An upper surface of the piezoelectric portion and an upper surface of the inclined portion may be coplanar.

A width of the reflective region may be smaller than a wavelength of a lateral wave generated when the central portion resonates.

The width of the reflective region may be 18%-32% of the wavelength of the lateral wave.

The width of the reflective region may be 0.4 µm-0.7 µm.

The insertion layer may have a thickness of 3000 Å-5000 Å.

An inclination angle of the inclined surface of the insertion layer may be 15°-25°.

The bulk acoustic wave resonator may include a frame layer disposed between the first electrode and the substrate, the frame layer may include an outer frame disposed in the reflective region and an inner frame disposed in the central portion, and the inner frame may have a continuous ring shape along a boundary between the central portion and the reflective region.

The frame layer may include a dielectric material.

The inner frame may have a width of 0.4 µm-0.8 µm.

The bulk acoustic wave resonator may include a temperature compensation portion disposed in the piezoelectric layer, and the temperature compensation portion may include a material having a positive temperature coefficient of elastic constant (TCE).

At least a portion of the temperature compensation portion may be in contact with the second electrode.

In another general aspect, a bulk-acoustic wave resonator includes: a substrate; a central portion including a first portion of a first electrode, a first portion of a piezoelectric layer, and a first portion of a second electrode disposed in order on the substrate; and a reflective region disposed laterally of the central portion and including a second portion of the first electrode, an insertion layer, a second portion of the piezoelectric layer, and a second portion of the second electrode. An upper surface of the first portion of the piezoelectric layer in the central portion and an upper surface of the second portion of the piezoelectric layer in the reflective region form a flat surface, a side surface of the insertion layer adjacent to the central portion has an inclined surface, and a side surface of the second electrode is disposed on the piezoelectric layer at a location corresponding to the inclined surface of the insertion layer.

An entire thickness of the reflective region and an entire thickness of the central portion are the same.

In another general aspect, a bulk-acoustic wave resonator includes: a substrate; a first electrode disposed on the substrate; a piezoelectric layer disposed on the first electrode; a second electrode disposed on the piezoelectric layer and having a flat upper surface; and an insertion layer disposed between a portion of the piezoelectric layer and a portion of the first electrode, the insertion layer including an inclined surface. An end of the second electrode overlaps the inclined surface of the insertion layer in a thickness direction of the bulk acoustic wave resonator.

The piezoelectric layer may include a piezoelectric portion directly disposed on the first electrode and a thickness changing portion disposed on the insertion layer, and an upper surface of the piezoelectric portion may form a flat surface with an upper surface of the thickness changing portion.

The thickness changing portion may include an inclined portion disposed on the inclined surface of the insertion layer and an extended portion that extends outwardly from the inclined portion.

Other features and aspects will be apparent from the following detailed description, the drawings, and the claims.

### BRIEF DESCRIPTION OF DRAWINGS

FIG. 1 is a plan diagram illustrating a bulk acoustic wave resonator according to an example.

FIG. 2 is a cross-sectional diagram taken along line I-I′ in FIG. 1.

FIG. 3 is a cross-sectional diagram taken along line II-II′ in FIG. 1.

FIG. 4 is a cross-sectional diagram taken along line III-III′ in FIG. 1.

FIG. 5 is graphs of a return loss of the bulk-acoustic wave resonator illustrated in FIG. 2 and a return loss of a general bulk-acoustic wave resonator.

FIGS. 6 and 7 are cross-sectional diagrams illustrating a bulk-acoustic wave resonator according to another example.

Throughout the drawings and the detailed description, the same reference numerals refer to the same elements. The drawings may not be to scale, and the relative size, proportions, and depictions of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent to one of ordinary skill in the art. The sequences of operations described herein are merely examples, and are not limited to those set forth herein, but may be changed as will be apparent to one of ordinary skill in the art, with the exception of operations necessarily occurring in a certain order. Also, descriptions of functions and constructions that would be well known to one of ordinary skill in the art may be omitted for increased clarity and conciseness.

The features described herein may be embodied in different forms, and are not to be construed as being limited to the examples described herein. Rather, the examples described herein have been provided so that this disclosure will be thorough and complete, and will fully convey the scope of the disclosure to one of ordinary skill in the art.

Herein, it is noted that use of the term “may” with respect to an example or embodiment, e.g., as to what an example or embodiment may include or implement, means that at least one example or embodiment exists in which such a feature is included or implemented while all examples and embodiments are not limited thereto.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms such as “above,” “upper,” “below,” and “lower” may be used herein for ease of description to describe one element’s relationship to another element as illustrated in the figures. Such spatially relative terms are intended to encompass different orientations of the device in use or operation in addition to the orientation depicted in the figures. For example, if the device in the figures is turned over, an element described as being “above” or “upper” relative to another element will then be “below” or “lower” relative to the other element. Thus, the term “above” encompasses both the above and below orientations depending on the spatial orientation of the device. The device may also be oriented in other ways (for example, rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes illustrated in the drawings may occur. Thus, the examples described herein are not limited to the specific shapes illustrated in the drawings, but include changes in shape that occur during manufacturing.

The features of the examples described herein may be combined in various ways as will be apparent after an understanding of the disclosure of this application. Further, although the examples described herein have a variety of configurations, other configurations are possible as will be apparent after an understanding of the disclosure of this application.

The drawings may not be to scale, and the relative sizes, proportions, and depiction of elements in the drawings may be exaggerated for clarity, illustration, and convenience.

Hereinafter, various examples will be described as below with reference to the attached drawings.

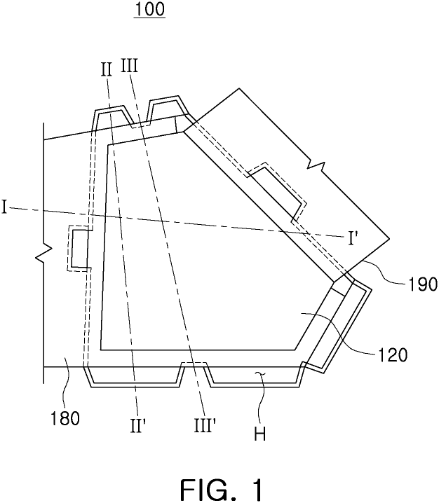

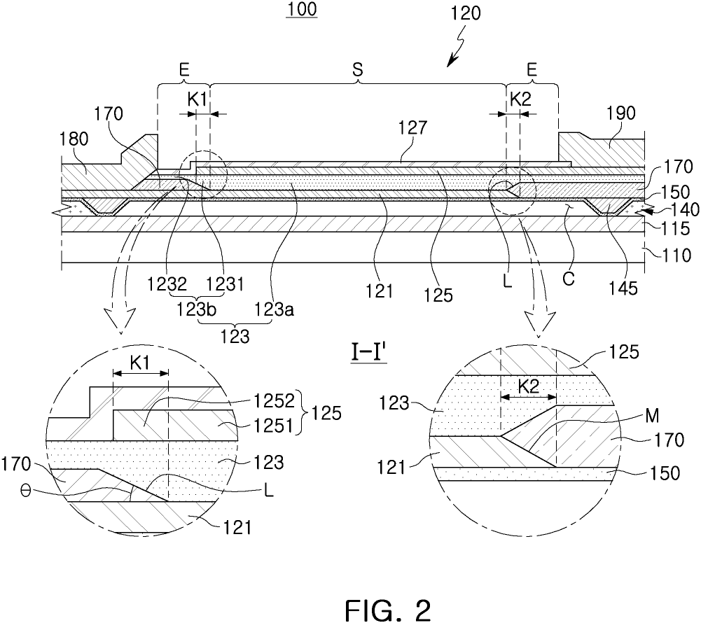

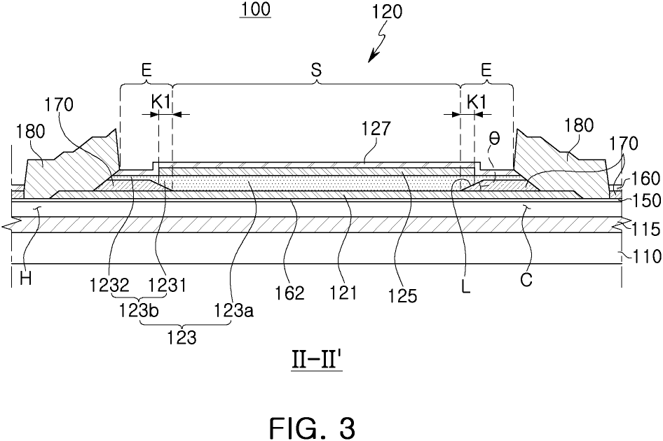

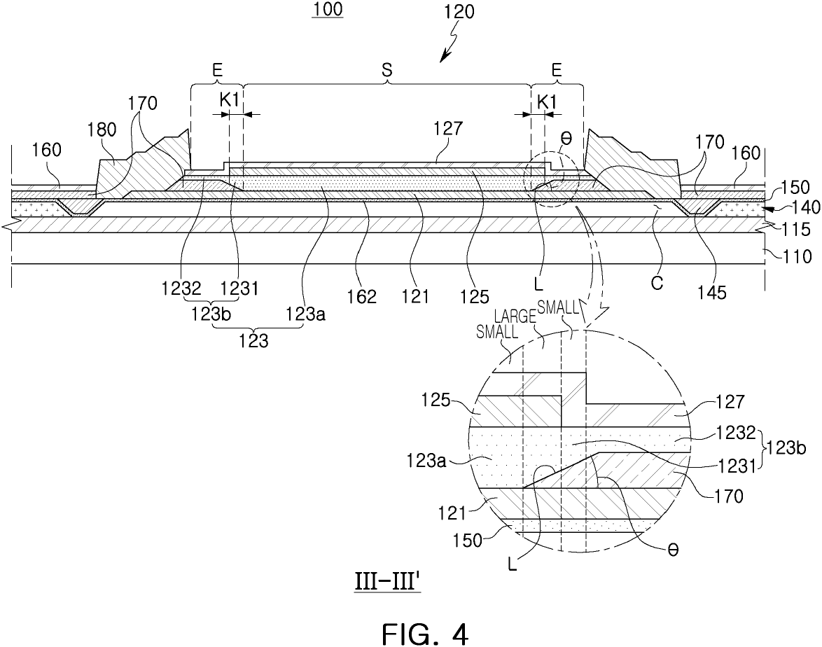

FIG. 1 is a plan diagram illustrating a bulk acoustic wave resonator according to an example. FIG. 2 is a cross-sectional diagram taken along line I-I′ in FIG. 1. FIG. 3 is a cross-sectional diagram taken along line II-II′ in FIG. 1. FIG. 4 is a cross-sectional diagram taken along line III-III′ in FIG. 1.

Referring to FIGS. 1 to 4, an acoustic resonator 100 may be implemented as a bulk acoustic wave resonator (BAW), and may include a substrate 110, a support layer 140, a resonant portion 120 and an insertion layer 170.

The substrate 110 may be configured as a silicon substrate. For example, a silicon wafer or a silicon on insulator (SOI) type substrate may be used as the substrate 110.

An insulating layer 115 may be disposed on an upper surface of the substrate 110 and may electrically isolate the substrate 110 from the resonant portion 120. Also, the insulating layer 115 may prevent the substrate 110 from being etched by an etching gas when the cavity C is formed during the manufacturing of process the acoustic resonator.

The insulating layer 115 may be formed of at least one of silicon dioxide (SiO₂), silicon nitride (Si₃N₄), aluminum oxide (Al₂O₃), and aluminum nitride (AIN), and may be formed by one of chemical vapor deposition, RF magnetron sputtering, and evaporation processes.

The support layer 140 may be formed on the insulating layer 115, and may be disposed around the cavity C and an etch stop portion 145 by surrounding the cavity C and the etch stop portion 145.

The cavity C may be formed as a void, and may be formed by removing a portion of a sacrificial layer formed in the process of preparing the support layer 140.

The etch stop portion 145 may be disposed along a boundary of the cavity C. The etch stop portion 145 may be provided to prevent etching beyond the cavity region during the process of forming the cavity C.

The membrane layer 150 may be formed on the support layer 140 and may form an upper surface of the cavity C. Accordingly, the membrane layer 150 may also be formed of a material not easily removed in the process of forming the cavity C.

For example, when a halide etching gas such as fluorine (F) or chlorine (Cl) is used to remove a portion (e.g., the cavity region) of the support layer 140, the membrane layer 150 may be formed of a material having low reactivity with the etching gas. In this case, the membrane layer 150 may include at least one of silicon dioxide (SiO₂) and silicon nitride (Si₃N₄).

Also, the membrane layer 150 may be configured as a dielectric layer including at least one of magnesium oxide (MgO), zirconium oxide (ZrO₂), aluminum nitride (AIN), lead zirconate titanate (PZT), gallium arsenide (GaAs), hafnium oxide (HfO₂), aluminum oxide (Al₂O₃), titanium oxide (TiO₂), or zinc oxide (ZnO), or may be configured as a metal layer including at least one of aluminum (Al), nickel (Ni), chromium (Cr), platinum (Pt), gallium (Ga), and hafnium (Hf). However, the configuration thereof is not limited thereto.

The resonant portion 120 may include a first electrode 121, a piezoelectric layer 123, and a second electrode 125. In the resonant portion 120, the first electrode 121, the piezoelectric layer 123, and the second electrode 125 may be laminated in order from the bottom. Accordingly, in the resonant portion 120, the piezoelectric layer 123 may be disposed between the first electrode 121 and the second electrode 125.

Since the resonant portion 120 is formed on the membrane layer 150, the membrane layer 150, the first electrode 121, the piezoelectric layer 123 and the second electrode 125 may be laminated in order and may form the resonant portion 120.

The resonant portion 120 may generate a resonant frequency and an anti-resonant frequency by resonating the piezoelectric layer 123 in response to a signal applied to the first electrode 121 and the second electrode 125.

As illustrated in FIG. 2, the resonant portion 120 may be divided into a central portion S and an extension portion E.

The central portion S may be a region in which the first electrode 121, the piezoelectric layer 123, and the second electrode 125 are flatly laminated, may be disposed in the center of the resonant portion 120, and may be substantially a resonance active region in which resonance occurs. For example, the central portion S may be a region of the resonance portion 120 in which an insertion layer 170, which will be described later, is not disposed.

The extension portion E may be a region extending from the central portion S to an external side of the central portion S, and may include the insertion layer 170. More specifically, the extension portion E may include the insertion layer 170 and the piezoelectric layer 123, and further may include at least one of the first electrode 121 and the second electrode 125.

With reference to a boundary between the central portion S and the extension portion E, the extension portion E may be formed in a continuous annular shape from an external side of the central portion S along the above-mentioned boundary. However, if desired, a portion of regions may be configured in a discontinuous annular shape.

Accordingly, as illustrated in FIG. 2, in the cross-section of the resonant portion 120 crossing the central portion S, the extension portions E may be disposed on both ends of the central portion S, respectively. Also, the insertion layer 170 may be disposed on both sides of the extension portion E disposed on both ends of the central portion S.

In the extension portion E, the piezoelectric layer 123 and the second electrode 125 may be disposed on the insertion layer 170.

The insertion layer 170 may include an inclined surface L having a thickness increasing in a direction away from the central portion S. Also, the piezoelectric layer 123 may have a flat upper surface. Accordingly, the portion of the piezoelectric layer 123 disposed in the extension portion E may be formed to have a thickness decreasing along the inclined surface L of the insertion layer 170 toward an external side.

In the example, the extension portion E may be included in the resonant portion 120, and accordingly, resonance may occur in the extension portion E as well. However, the configuration is not limited thereto, and, depending on the structure of the extension portion E, resonance may not occur in the extension portion E, and resonance may only occur in the central portion S.

The first electrode 121 and the second electrode 125 may be formed of a conductor, and may be formed of gold, molybdenum, ruthenium, iridium, aluminum, platinum, titanium, tungsten, palladium, tantalum, chromium, nickel or a metal including at least one of the above-mentioned elements, but the configuration thereof is not limited thereto.

In the resonant portion 120, the first electrode 121 may be configured to have a region larger than the second electrode 125, and a first metal layer 180 may be disposed along an outer edge of the first electrode 121 on the first electrode 121. Accordingly, the first metal layer 180 may be spaced apart from the second electrode 125 by a predetermined distance, and may surround the resonant portion 120.

Since the first electrode 121 is disposed on the membrane layer 150, the first electrode 121 may be formed to be flat. Also, since the second electrode 125 is disposed on the piezoelectric layer 123, the second electrode 125 may be formed to be flat according to the shape of the piezoelectric layer 123. Accordingly, the distance between the first electrode 121 and the second electrode 125 in the resonant portion 120 may be constant or uniform.

The first electrode 121 may be used as one of an input electrode and an output electrode for inputting and outputting an electrical signal such as a radio frequency (RF) signal.

The second electrode 125 may extend along the entire length of the central portion S, and may be partially disposed in the extension portion E. More specifically, the second electrode 125 may be disposed to cover the entire piezoelectric layer 123 disposed in the central portion S, and in the extension portion E, the side surface of the second electrode 125 forming the end of the second electrode 125 may be disposed on the piezoelectric layer 123 at a location corresponding to the inclined surface L of the insertion layer 170. For example, the side surface of the second electrode 125 may be disposed at a location corresponding to the inclined surface L of the insertion layer 170.

In the example, the side surface of the second electrode 125 may refer to a portion illustrated as a side surface in the cross-sectional diagram illustrated in FIG. 2. Accordingly, on a cross-section of the resonant portion 120 crossing the central portion S, the end, which may be a side surface of the second electrode 125, may be disposed in the extension portion E. Also, at least a portion of an end of the second electrode 125 disposed in the extension portion E may be disposed to overlap the insertion layer 170. More specifically, an end of the second electrode 125 may be disposed to overlap the inclined surface L of the insertion layer 170.

Here, the overlapping may refer to the overlap between the shape of the second electrode 125 projected on the plane and the inclined surface L of the insertion layer 170 when the second electrode 125 is projected on the plane on which the insertion layer 170 is disposed.

As illustrated in FIGS. 1 and 2, at least a portion of the second electrode 125 may be connected to a second metal layer 190 through the extension portion E. Accordingly, in the portion of the second electrode 125 connected to the second metal layer 190, the end of the second electrode 125 may not be disposed in the extension portion E.

Accordingly, in the example, the end of the second electrode 125 may refer to the side surface of the portion of the second electrode 125 other than the portion penetrating the extension portion E and connected to the second metal layer 190.

The second electrode 125 may be used as one of an input electrode and an output electrode for inputting and outputting an electrical signal such as a radio frequency (RF) signal. That is, when the first electrode 121 is used as an input electrode, the second electrode 125 may be used as an output electrode, and when the first electrode 121 is used as an output electrode, the second electrode 125 may be used as an input electrode.

As illustrated in FIG. 4, when the end of the second electrode 125 is disposed in the extension portion E, a local structure of acoustic impedance of the resonant portion 120 may be formed in a small/large/small structure from the central portion S, such that reflectance of reflecting a lateral wave into the resonant portion 120 may increase. Accordingly, most of the lateral waves may not escape the resonant portion 120 and may be reflected into the resonant portion 120, such that the performance of the acoustic resonator may improve.

The lateral wave may include a wave traveling along the direction of the plane of the resonant portion and forming spurious resonance.

The piezoelectric layer 123 may be configured to generate a piezoelectric effect V converting electrical energy into mechanical energy in the form of acoustic waves, and may be formed on the first electrode 121 and the insertion layer 170.

As the material of the piezoelectric layer 123, zinc oxide (ZnO), aluminum nitride (AIN), doped aluminum nitride, lead zirconate titanate, quartz (Quartz), or the like may be selectively used. The doped aluminum nitride may further include a rare earth metal, a transition metal, or an alkaline earth metal. The rare earth metal may include at least one of scandium (Sc), erbium (Er), yttrium (Y), and lanthanum (La). The transition metal may include at least one of hafnium (Hf), titanium (Ti), zirconium (Zr), tantalum (Ta), and niobium (Nb). The alkaline earth metal may include magnesium (Mg).

When the content of elements doped into aluminum nitride (AIN) to improve piezoelectric properties is less than 0.1 at%, piezoelectric properties higher than that of aluminum nitride (AIN) may not be implemented, and when the content of elements exceeds 30 at%, the manufacturing and composition control for deposition may be difficult such that a non-uniform phase may be formed.

Accordingly, in the example, the content of elements doped into aluminum nitride (AIN) may be in the range of 0.1 to 30 at%.

In the example, aluminum nitride (AIN) doped with scandium (Sc) may be used for the piezoelectric layer. In this case, the piezoelectric constant may increase such that kₜ² of the acoustic resonator may increase.

The piezoelectric layer 123 may include a piezoelectric portion 123a disposed in the central portion S, and a thickness changing portion 123b disposed in the extension portion E.

The piezoelectric portion 123a may be configured to be directly laminated on the upper surface of the first electrode 121. Accordingly, the piezoelectric portion 123a may be interposed between the first electrode 121 and the second electrode 125 and may be formed to be flat along with the first electrode 121 and the second electrode 125.

The thickness changing portion 123b may be defined as a region extending outwardly from the piezoelectric portion 123a and disposed within the extension portion E, and may refer to a portion disposed on the insertion layer 170.

In the bulk-acoustic wave resonator 100, spacing distances between the membrane layers 150 and the second electrodes 125 may be constant or uniform, and accordingly, the upper surface of the piezoelectric layer 123 may be formed to be flat.

In the example, the configuration of being constant or flat may include a minute thickness deviation generated due to a process error, and may refer to a configuration without an intentional step difference or a curve.

Due to this configuration, the thickness of the piezoelectric layer 123 may be reduced by the thickness of the insertion layer 170 in the thickness changing portion 123b. Accordingly, the thickness of the piezoelectric layer 123 may change with reference to the boundary between the piezoelectric portion 123a and the thickness changing portion 123b, and the thickness of the thickness changing portion 123b may be reduced in inverse proportion to the increase of the thickness of the insertion layer 170.

The thickness changing portion 123b may be divided into an inclined portion 1231 and an extended portion 1232.

The inclined portion 1231 may be disposed on the inclined surface L of the insertion layer 170, and may refer to a portion of which a thickness may continuously change along the inclined surface L of the insertion layer 170. For example, the thickness of the inclined portion 1231 may decrease in a direction away from the piezoelectric portion 123a.

The extended portion 1232 may extend outwardly from the inclined portion 1231, and may refer to a portion disposed on the insertion layer 170 and having a constant thickness. Accordingly, the thickness of the extended portion 1232 may be less than the thickness of the piezoelectric portion 123a.

As described above, the upper surface of the piezoelectric layer 123 may be formed to be flat. Accordingly, the upper surface of the piezoelectric portion 123a and the upper surface of the inclined portion 1231 may be disposed on the same plane.

The insertion layer 170 may be disposed between the first electrode 121 and the second electrode 125, and in the example, the insertion layer 170 may be disposed along the surface formed by the membrane layer 150, the first electrode 121, and the etch stop portion 145. The insertion layer 170 may be partially disposed in the resonant portion 120, and at least a portion thereof may be disposed between the first electrode 121 and the piezoelectric layer 123.

The insertion layer 170 may be disposed around the central portion S and may support the thickness changing portion 123b of the piezoelectric layer 123. Accordingly, the thickness of the thickness changing portion 123b of the piezoelectric layer 123 may be reduced according to the shape of the insertion layer 170.

In the example, the insertion layer 170 may be disposed in a region other than the central portion S. For example, the insertion layer 170 may be disposed on a portion of the region other than the central portion S on the substrate 110, or may be disposed on the entire region.

A side surface of the insertion layer 170 opposing the central portion S may be formed as the inclined surface L having a constant inclination angle θ. Accordingly, the insertion layer 170 on the inclined surface L may have thickness increasing in a direction away from the central portion S.

Since the insertion layer 170 may also perform a function of protecting the first electrode 121 when the piezoelectric layer 123 is patterned in the process of manufacturing the bulk-acoustic wave resonator 100, the insertion layer 170 may have a predetermined thickness or more. Also, when the thickness of the insertion layer 170 is excessively thick, difficulty of the process on an external side of the resonant portion 120 may increase. In consideration of this, in the example, the thickness of the insertion layer 170 may be formed in a range of 3000 Å-5000 Å.

Also, when the inclination angle θ of the side of the insertion layer 170 is excessively narrow (e.g., 5° or less), to obtain the thickness, the thickness of the insertion layer 170 may need to have a thin thickness or the area of the inclined surface L may need to be excessively increased, which may be difficult to implement.

When the inclination angle θ of the side of the insertion layer 170 is excessively wide (e.g., 70° or more), crystallinity of the piezoelectric layer 123 deposited on the upper surface of the insertion layer 170 may be lowered and cracks may be easily created.

Accordingly, in the example, the inclination angle θ of the inclined surface L may be formed in the range of 5°-70°.

Referring to FIG. 2, a side surface (e.g., an end) of the first electrode 121 may be formed as an inclined surface. Also, the insertion layer 170 on the right side, disposed on the end side of the first electrode 121, may not cover the flat upper surface of the first electrode 121 and may be configured to be in contact with an inclined surface M (hereinafter referred to as a first inclined surface M) formed on the end of the first electrode 121. For example, in the portion in which the first inclined surface M is formed, the insertion layer 170 may be disposed to extend from the first inclined surface M rather than being laminated on the first electrode 121.

Accordingly, the insertion layer 170 may be disposed to overlap the first inclined surface M of the first electrode 121, and the region defined by the first inclined surface M may be configured as a reflective region K2.

The insertion layer 170 may be formed of a dielectric material such as silicon oxide (SiO₂), aluminum nitride (AIN), aluminum oxide (Al₂O₃), silicon nitride (Si₃N₄), magnesium oxide (MgO), zirconium oxide (ZrO₂), lead zirconate titanate (PZT), gallium arsenide (GaAs), hafnium oxide (HfO₂), titanium oxide (TiO₂), zinc oxide (ZnO), or the like, and may be formed of a material different from that of the piezoelectric layer 123.

Also, the insertion layer 170 may be implemented by a metal material. When the bulk acoustic wave resonator 100 is used for 5G communications, since heat may be extensively generated in a resonator, it may be necessary to smoothly radiate the heat generated in the resonant portion 120. To this end, the insertion layer 170 may be formed of an aluminum alloy material including scandium (Sc).

Also, the insertion layer 170 may be formed as a SiO₂ thin film implanted with nitrogen (N) or fluorine (F).

As the insertion layer 170 is provided, acoustic impedance mismatch of the extension portion E may increase further than that of the central portion S. Accordingly, the extension portion E may function as a frame reflecting a lateral acoustic wave directed toward an external side of the resonant portion 120 among the lateral acoustic waves generated in the central portion S toward the central portion S, thereby reducing energy loss of the wave. Accordingly, a high Q-factor may be secured.

A high Q-factor may increase the blocking properties of other frequency bands in implementing a filter or a duplexer as a bulk-acoustic wave resonator.

A protective layer 127 may be disposed along the surface of the acoustic resonator 100 and may protect the acoustic resonator 100. The protective layer 127 may be disposed along the surface formed by the second electrode 125 and the thickness changing portion 123b of the piezoelectric layer 123.

The protective layer 127 may be formed as a single layer, or may be formed by laminating two or more layers having different materials. Also, the protective layer 127 may be partially removed for frequency control in a final process. For example, the thickness of the protective layer 127 may be adjusted in a frequency trimming process.

As the protective layer 127, a dielectric layer including silicon nitride (Si₃N₄), silicon oxide (SiO₂), magnesium oxide (MgO), zirconium oxide (ZrO₂), aluminum nitride (AIN), lead lyrconate titanate (PZT), gallium arsenide (GaAs), hafnium oxide (HfO₂), aluminum oxide (Al₂O₃), titanium oxide (TiO₂), or zinc oxide (ZnO) may be used, but the configuration thereof is not limited thereto.

The first electrode 121 and the second electrode 125 may extend externally of the resonant portion 120. Also, the first metal layer 180 and the second metal layer 190 may be disposed on the upper surfaces of the extension portions E, respectively. Accordingly, the first metal layer 180 may be bonded to the first electrode 121, and the second metal layer 190 may be bonded to the second electrode 125.

The first metal layer 180 and the second metal layer 190 may be formed of one of gold (Au), a gold-tin (Au—Sn) alloy, copper (Cu), a copper-tin (Cu—Sn) alloy, aluminum (Al), and an aluminum alloy. Here, the aluminum alloy may be an aluminum-germanium (Al—Ge) alloy or an aluminum-scandium (Al—Sc) alloy.

As illustrated in FIG. 3, the first electrode 121 in the resonant portion 120 may have a larger area than that of the second electrode 125, and as illustrated in FIG. 1, the first metal layer 180 may be disposed along the circumference of the resonant portion 120. Accordingly, the first metal layer 180 may be disposed to surround the second electrode 125, but the configuration thereof is not limited thereto.

The resonant portion 120 configured as above may be spaced apart from the substrate 110 through the cavity C disposed below the membrane layer 150. Accordingly, the membrane layer 150 may be disposed below the first electrode 121 and the insertion layer 170 and may support the resonant portion 120.

The cavity C may be formed as a void, and may be formed by removing a portion of the support layer 140 by supplying an etching gas (or an etching solution) to an inlet hole H (in FIG. 1).

The bulk acoustic wave resonator 100 may include reflective regions K1 and K2 to increase reflection efficiency of the lateral acoustic wave.

In the example, the reflective regions K1 and K2 may be disposed in the extension portion E, and may include the first electrode 121, the insertion layer 170, the piezoelectric layer 123, and the second electrode 125. For example, the reflective regions K1 and K2 may refer to regions in which the first electrode 121, the insertion layer 170, the piezoelectric layer 123, and the second electrode 125 are laminated in sequence.

Accordingly, as illustrated in FIG. 2, the second electrode 125 may include a first region 1251 disposed in the central portion S and a second region 1252 disposed in the reflective region K1. The first region 1251 may be disposed entirely in the central portion S, and the second region 1252 may be disposed in a portion of the extension portion E.

As the upper surface of the piezoelectric layer 123 is formed to be flat in the central portion S and the reflective regions K1 and K2, the second electrode 125 disposed in the central portion S and the reflective regions K1 and K2 may also be formed to be flat. Accordingly, the first region 1251 and the second region 1252 of the second electrode 125 may be disposed on the same plane.

In the example, the entire thickness of the reflective regions K1 and K2 and the entire thickness of the central portion S may be the same. Specifically, the entire thickness of the first electrode 121, the insertion layer 170, the piezoelectric layer 123, and the second electrode 125 laminated in the reflective regions K1 and K2 may be the same as the entire thickness of the first electrode 121, the piezoelectric layer 123, and the second electrode 125 laminated in the central portion S.

Referring to FIG. 2, the reflective regions K1 and K2 may be formed in a continuous annular shape along the boundary between the central portion S and the extension portion E on an external side of the central portion S with reference to the boundary. Accordingly, the reflective regions K1 and K2 may be disposed on an external side of the central portion S, and as illustrated in FIG. 2, in the cross-section of the resonant portion 120 crossing the central portion S, the reflective regions K1 and K2 may be disposed on both ends of the central portion S, respectively. Also, in FIG. 2, the left reflective region K1 and the right reflective region K2 may be connected to each other.

The width of the reflective regions K1 and K2 may refer to a horizontal distance between the reflective regions K1 and K2 in the cross-section illustrated in FIG. 2. Although two reflective regions K1 and K2 are illustrated in FIG. 2, in the example, the width of the reflective regions K1 and K2 may refer to the width of each reflective region K1 and K2, and accordingly, the two reflective regions K1 and K2 may be formed to have the same width or similar widths.

The width of the reflective region K1 illustrated on the left in FIG. 2 may be less than the width formed by the inclined surface L of the insertion layer 170. Also, the width of the reflective region K2 illustrated on the right may be formed as a horizontal distance between the end of the insertion layer 170 and the end of the first electrode 121. Here, the reflective region K1 illustrated on the left in FIG. 2 may refer to a reflective region formed on the flat upper surface of the first electrode 121, and the reflective region K2 illustrated on the right may refer to the reflective region formed on the side surface (the inclined surface) of the first electrode 121.

In the example, the width of the reflective regions K1 and K2 may be formed to be less than the wavelength of the lateral wave generated when the central portion S resonates.

Generally, the frequency band in which the filter using the bulk-acoustic wave resonator 100 is used may be 1.75 GHz-3.55 GHz, and the wavelength of the lateral wave approximate to resonance and anti-resonance frequencies may be approximately 1 µm to 4 µm.

A lateral wave may be naturally generated due to properties of the material and structure when a bulk-acoustic wave resonator resonates and generates a vertical wave. This lateral wave may be spread in the plane direction (or horizontal direction) of the resonator 100, may form a specific wavelength and a specific mode through mode conversion. A lateral wave present between a resonant frequency and an antiresonant frequency in the above frequency band may include four modes.

When the resonance frequency is in the 3.55 GHz band, a lateral wave wavelength of the mode having the largest effect on the reflection performance among the four modes may be 2.2 µm level. It is indicated that, in consideration of this, when the width of the reflective regions K1 and K2 is formed with 0.4 µm-0.7 µm (18%-32%) corresponding to a quarter level of the wavelength, reflectance with respect to the lateral wave may significantly increase.

Here, 0.4 µm-0.7 µm (18%-32%) may be a specified range in which attenuation performance is equal to or greater than a specific value by measuring the attenuation performance of the bulk-acoustic wave resonator while changing the width of the reflective regions K1 and K2. Here, the attenuation performance of the resonator may refer to an absolute value of a minimum value of a transmission coefficient S21.

Through various experiments as above, it is indicated that, when the width of the reflective regions K1 and K2 is formed in the range of about ¼ of the wavelength of the lateral wave, reflectance may increase, such that the Q-factor of the anti-resonance point may increase.

Accordingly, in the example, among the reflective regions K1 and K2, a width of the reflective region K1 formed on the flat upper surface of the first electrode 121 may be formed in 18%-32%, about ¼ of the lateral wave wavelength, and for example, the width may be formed in the range of 0.4 µm-0.7 µm.

The reflective region K1 may be disposed in the inclined surface L region of the insertion layer 170.

Also, as described above, the thickness of the insertion layer 170 may be formed to be 3000 Å-5000 Å. When the inclination angle of the side surface of the insertion layer 170 is formed to be 15°-25° in the thickness range, the width of the portion in which the inclined surface L is formed may be formed in the range of 0.64 µm-1.87 µm. In this case, even when the width of the reflective region K1 is formed in the range of 0.4 µm to 0.7 µm, most of the width of the reflective region K1 may be disposed within the range of the inclined plane L of the insertion layer 170.

Accordingly, in the insertion layer 170, the inclination angle θ of the inclined surface L may be formed in the range of 15°-25°.

When the thickness of the insertion layer 170 is 3000 Å and the inclination angle of the side surface of the insertion layer 170 is 25°, the width of the portion in which the inclined surface L is formed may be 0.64 µm, the smallest, and in this case, it may be difficult to form the width of K1 to be 0.7 µm. Accordingly, in this case, the width of the reflective region K1 may be formed in the range of 0.4 µm to 0.6 µm. However, if desired, by increasing the thickness of the insertion layer 170 or decreasing the inclination angle θ of the side surface of the insertion layer 170, the reflective region K1 may be disposed within the region of the inclined surface L of the insertion layer 170.

The bulk-acoustic wave resonator 100 configured as described above may reduce loss as compared to a general acoustic resonator structure, and may improve processability for deposition and patterning of the second electrode 125

In the general bulk-acoustic wave resonator, the thickness of the extension portion E may be greater than that of the central portion S. Since the frequency is inversely proportional to the thickness, partial resonance may occur in a lower frequency band than in the central portion S in the extension portion E having an increased thickness, such that loss may occur in the low-band region. Accordingly, this difference may act as a factor to increase insertion loss of the bulk-acoustic wave resonator.

Also, in terms of the manufacturing process, when a curve is formed in the piezoelectric layer 123, etching uniformity may be lowered in the process of patterning the second electrode 125 laminated on the piezoelectric layer 123, such that process difficulty may increase. Also, as the second electrode 125 is deposited on the curved portion, crystallinity of the second electrode 125 may be reduced, and the second electrode 125 may be partially disconnected or resistance may increase due to cracks.

However, in the bulk-acoustic wave resonator 100, the upper surface of the piezoelectric layer 123 may be formed to be flat, such that the reflective regions K1 and K2 and the central portion S may have the same thickness or similar thicknesses. Accordingly, the same reflection function for the lateral wave may be provided, and loss properties in the low-band may be addressed. Also, since processability for deposition and patterning of the second electrode 125 may improve, such that a manufacturing process may be easily performed, and accordingly, a yield may increase.

The process of flattening the upper surface of the piezoelectric layer 123 may be implemented through a chemical mechanical polishing (CMP) process. For example, the flattening may include laminating the piezoelectric layer 123 on the insertion layer 170 and the first electrode 121, partially forming a mask pattern on the piezoelectric layer 123, and flattening the upper surface of the piezoelectric layer 123 by removing a protrusion (a portion without a mask pattern) of the piezoelectric layer 123 using a CMP process. However, the configuration thereof is not limited thereto.

Also, the bulk-acoustic wave resonator 100 may improve loss properties between a resonance point and an anti-resonance point by forming the width of the reflective regions K1 and K2 in the range of 0.4 µm to 0.7 µm. As described above, when the width of the reflective regions K1 and K2 is formed in the range of 0.4 µm to 0.7 µm, the Q-factor at the anti-resonance point may increase. Accordingly, the bulk-acoustic wave resonator 100 may reduce loss in the low-band section and may also reduce loss between the resonance point and the anti-resonance point, such that loss may be reduced throughout the entire section of the resonant frequency band.

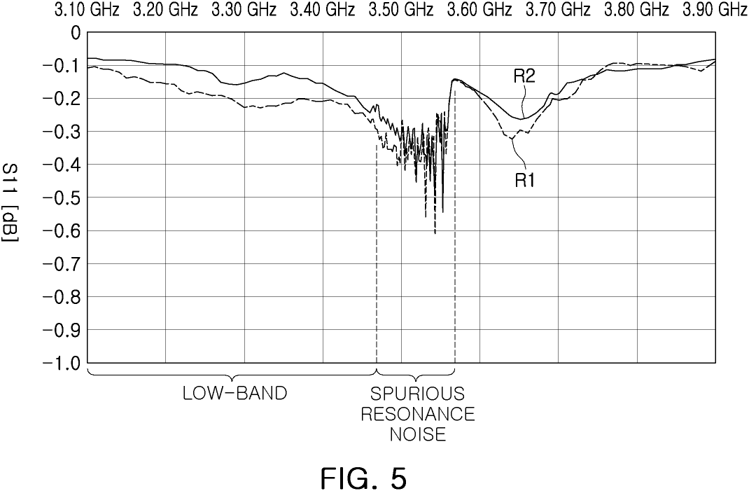

FIG. 5 illustrates graphs of a return loss of the bulk-acoustic wave resonator illustrated in FIG. 2 and a return loss of a general bulk-acoustic wave resonator. R1 is a graph of the conventional bulk-acoustic wave resonator, and R2 is a graph of the bulk-acoustic wave resonator 100 according to the example.

Referring to FIG. 5, since the thickness of the bulk-acoustic wave resonator R2 in the example may not increase in the extension portion E, partial resonance may be prevented in the low-band such that return loss may be reduced. Also, since the return loss is reduced throughout the entire frequency band, improved performance may be provided as compared to the general bulk-acoustic wave resonator R1.

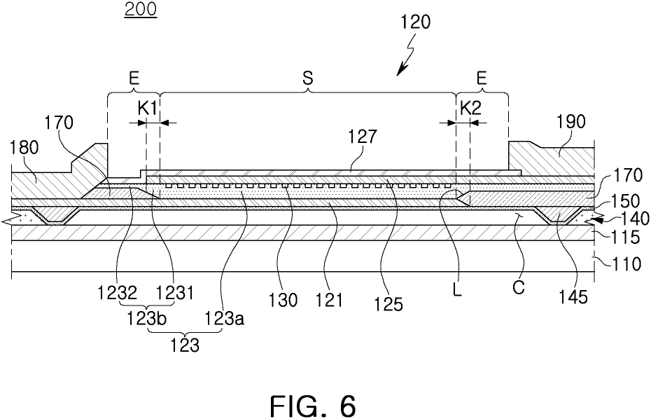

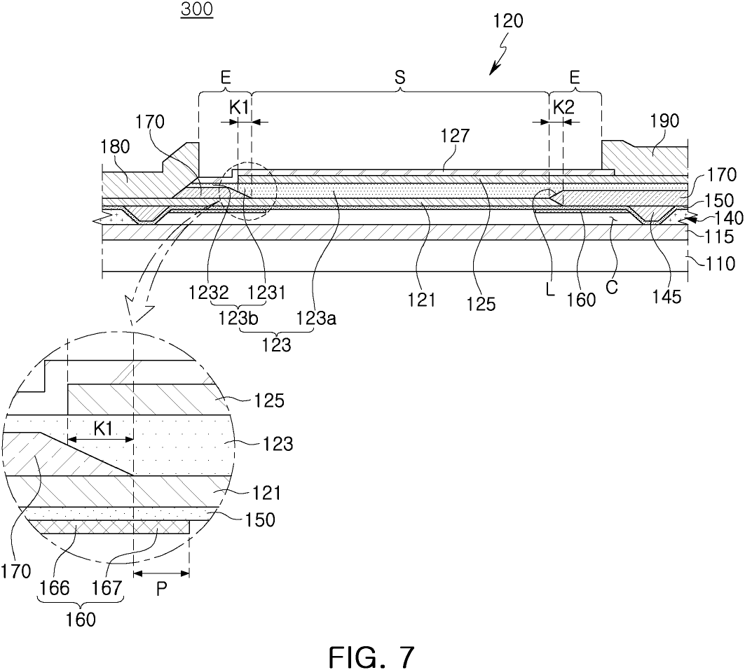

FIGS. 6 and 7 are cross-sectional diagrams illustrating a bulk-acoustic wave resonator according to another example.

Referring to FIG. 6, the bulk-acoustic wave resonator 200 may include a temperature compensation portion 130.

The temperature compensation portion 130 may be inserted to and disposed on the upper surface of the piezoelectric layer 123 in the form of a pattern. For example, the temperature compensation portion 130 may be formed by forming a plurality of grooves on the upper surface of the piezoelectric layer 123 and filling the grooves with a material having a temperature compensation function.

In the example, SiO₂ may be used as a material having a temperature compensation function. For example, in the bulk-acoustic wave resonator 200, the temperature compensation portion 130 formed of SiO₂ may be dispersedly disposed on the upper surface of the piezoelectric layer 123 such that frequency fluctuations caused by temperature changes may be prevented.

This will be described in greater detail as below.

Most of the materials forming the resonant portion 120 have a negative temperature coefficient of elastic constant (TCE). The TCE may refer to a temperature coefficient for stiffness, and when the TCE is negative, the resonance frequency may decrease as the temperature increases.

Also, in the bulk acoustic wave resonator 200, temperature coefficient of frequency (TCF) performance may be important. TCF may be properties indicating a gradual change in the resonant frequency according to the temperature, and may be determined by physical properties of material.

When the TCF properties is bad (e.g., when the absolute value increases), the change in the resonance frequency may increase according to the temperature change, such that it may be difficult to select only a desired bandwidth. Conversely, as the absolute value of TCF decreases, the change in the resonance frequency according to the temperature change may decrease. Accordingly, it may be desirable to maintain the TCF close to zero as for the bulk acoustic wave resonator.

In the bulk acoustic wave resonator 200, the frequency may be a function of physical properties (density (ρ) and stiffness (C)) and a thickness (t), and as for a single material, the TCF may be represented as below.

$$\begin{matrix}\frac{1}{f} \frac{d f}{d T} = \frac{1}{2} \left(\frac{1}{c} \frac{d c}{d T} \text{-} \frac{1}{\text{ρ}} \frac{d \text{ρ}}{d T}\right) \text{-} \frac{1}{t} \frac{d t}{d T} = \frac{1}{2} \left(\frac{1}{c} \frac{d c}{d T} + \frac{1}{V} \frac{d V}{d T}\right) \text{-} \frac{1}{t} \frac{d t}{d T} = \\ \frac{1}{2} \left(\frac{1}{c} \frac{d c}{d T} + \frac{1}{t} \frac{d t}{d T}\right)\end{matrix}$$

Here, V may refer to the volume of the material, T may refer to the temperature, and t may refer to the thickness. Also,

$$\frac{1}{f} \frac{d f}{d T}$$

may be the TCF, indicating the temperature coefficient of frequency,

$$\frac{1}{c} \frac{d c}{d T}$$

may be the TCE, indicating the temperature coefficient of elastic constant for stiffness, and

$$\frac{1}{t} \frac{d t}{d T}$$

may be the CTE, indicating a thermal expansion coefficient. Thus, TCF properties may be determined by TCE and CTE, and in the actual bulk acoustic wave resonator, the TCF may be determined by the influence of the TCE and CTE values of the materials forming the layers and the thickness of each layer. The TCF properties may have a relatively large influence on the TCE.

The bulk-acoustic wave resonator 200 may reduce frequency fluctuations by offsetting and compensating for properties of the TCE through the temperature compensation portion 130. As described above, most of the materials included in the resonant portion 120 may have a negative temperature coefficient of elastic constant (TCE). Accordingly, the temperature compensation portion 130 may include a material having a positive TCE, such as SiO₂.

When the upper surface of the piezoelectric layer 123 is formed to be flat, a groove may be formed in the upper surface of the piezoelectric layer 123, the material forming the temperature compensation portion 130 may be filled in the groove, and the upper surface of the piezoelectric layer 123 and the temperature compensation portion 130 may be formed to be flat through the flattening process. Accordingly, at least a portion of the temperature compensation portion 130 may be in contact with the second electrode 125 laminated on the upper surface of the piezoelectric layer 123.

In the general bulk-acoustic wave resonator in which the extension portion E is formed to have a great thickness, it may be difficult to form a temperature compensation portion on the upper surface of the piezoelectric layer 123 due to the curvature of the piezoelectric layer 123, whereas, in the bulk-acoustic wave resonator in the example, since the upper surface of the piezoelectric layer 123 is formed to be flat, the temperature compensation portion 130 may be easily formed.

Referring to FIG. 7, the bulk-acoustic wave resonator 300 may further include a frame layer 160.

The frame layer 160 may be laminated on the lower surface of the membrane layer 150. However, the configuration thereof is not limited thereto, and various modifications such as disposing the frame layer 160 between the membrane layer 150 and the first electrode 121 may be made.

The frame layer 160 may be disposed in the extension portion E and may surround the central portion S, and at least a portion thereof may extend toward the central portion S and may be disposed in the central portion S.

More specifically, the frame layer 160 may be divided into an outer frame 166 disposed in the reflective regions K1 and K2 or the extension portion E, and an inner frame 167 extending from the outer frame 166 and disposed in the central portion S. The inner frame 167 may be formed in a continuous annular shape along the boundary between the central portion S and the extension portion E on an internal side of the central portion S with respect to the boundary.

The frame layer 160 may be provided to increase reflectance of a lateral wave. To increase reflectance of a lateral wave, a large acoustic impedance mismatch may be formed on the boundary between the reflective regions K1 and K2.

To this end, the frame layer 160 may be formed of a dielectric material, and may be formed to have a thickness less than that of the first electrode 121. However, the configuration thereof is not limited thereto.

A width P of the inner frame 167 may be varied in consideration of the above-described reflectance. For example, the width P of the inner frame 167 may be formed in the range of 0.4 µm-0.8 µm, but the configuration thereof is not limited thereto.

According to the aforementioned examples, the bulk acoustic wave resonator may reduce loss and may improve processability for deposition and patterning of the second electrode.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed to have a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A bulk acoustic wave resonator, comprising:
a substrate;
a central portion comprising a first portion of a first electrode, a first portion of a piezoelectric layer, and a first portion of a second electrode laminated in order on the substrate; and
a reflective region disposed laterally of the central portion and comprising a second portion of the first electrode, an insertion layer, a second portion of the piezoelectric layer, and a second portion of the second electrode,
wherein a side surface of the insertion layer adjacent to the central portion has an inclined surface,
wherein the first portion of the second electrode and the second portion of the second electrode are coplanar, and
wherein an end of the second electrode overlaps the inclined surface of the insertion layer in the reflective region.

2. The bulk acoustic wave resonator of claim 1, wherein a combined thickness of the second portion of the first electrode, the insertion layer, the second portion of the piezoelectric layer, and the second portion of the second electrode disposed in the reflective region is equal to a combined thickness of the first portion of the first electrode, the first portion of the piezoelectric layer, and the first portion of the second electrode disposed in the central portion.

3. The bulk acoustic wave resonator of claim 1,
wherein the first portion of the piezoelectric layer comprises a piezoelectric portion disposed in the central portion and the second portion of the piezoelectric layer comprises an inclined portion disposed on the inclined surface of the insertion layer, and
wherein the inclined portion has a thickness decreasing in a direction away from the piezoelectric portion.

4. The bulk acoustic wave resonator of claim 3, wherein an upper surface of the piezoelectric portion and an upper surface of the inclined portion are coplanar.

5. The bulk acoustic wave resonator of claim 1, wherein a width of the reflective region is smaller than a wavelength of a lateral wave generated when the central portion resonates.

6. The bulk acoustic wave resonator of claim 5, wherein the width of the reflective region is 18%-32% of the wavelength of the lateral wave.

7. The bulk acoustic wave resonator of claim 5, wherein the width of the reflective region is 0.4 µm-0.7 µm.

8. The bulk acoustic wave resonator of claim 5, wherein the insertion layer has a thickness of 3000 Å-5000 Å.

9. The bulk acoustic wave resonator of claim 1, wherein an inclination angle of the inclined surface of the insertion layer is 15°-25°.

10. The bulk acoustic wave resonator of claim 1, further comprising:
a frame layer disposed between the first electrode and the substrate,
wherein the frame layer comprises an outer frame disposed in the reflective region and an inner frame disposed in the central portion, and
wherein the inner frame has a continuous ring shape along a boundary between the central portion and the reflective region.

11. The bulk acoustic wave resonator of claim 10, wherein the frame layer comprises a dielectric material.

12. The bulk acoustic wave resonator of claim 10, wherein the inner frame has a width of 0.4 µm-0.8 µm.

13. The bulk acoustic wave resonator of claim 1, further comprising:
a temperature compensation portion disposed in the piezoelectric layer,
wherein the temperature compensation portion comprises a material having a positive temperature coefficient of elastic constant (TCE).

14. The bulk acoustic wave resonator of claim 13, wherein at least a portion of the temperature compensation portion is in contact with the second electrode.

15. A bulk-acoustic wave resonator, comprising:
a substrate;
a central portion comprising a first portion of a first electrode, a first portion of a piezoelectric layer, and a first portion of a second electrode disposed in order on the substrate; and
a reflective region disposed laterally of the central portion and comprising a second portion of the first electrode, an insertion layer, a second portion of the piezoelectric layer, and a second portion of the second electrode,
wherein an upper surface of the first portion of the piezoelectric layer in the central portion and an upper surface of the second portion of the piezoelectric layer in the reflective region form a flat surface,
wherein a side surface of the insertion layer adjacent to the central portion has an inclined surface, and
wherein a side surface of the second electrode is disposed on the piezoelectric layer at a location corresponding to the inclined surface of the insertion layer.

16. The bulk acoustic wave resonator of claim 15, wherein an entire thickness of the reflective region and an entire thickness of the central portion are the same.

17. A bulk acoustic wave resonator, comprising:
a substrate;
a first electrode disposed on the substrate;
a piezoelectric layer disposed on the first electrode; and
a second electrode disposed on the piezoelectric layer and having a flat upper surface;
an insertion layer disposed between a portion of the piezoelectric layer and a portion of the first electrode, the insertion layer comprising an inclined surface,
wherein an end of the second electrode overlaps the inclined surface of the insertion layer in a thickness direction of the bulk acoustic wave resonator.

18. The bulk acoustic wave resonator of claim 17, wherein the piezoelectric layer comprises a piezoelectric portion directly disposed on the first electrode and a thickness changing portion disposed on the insertion layer, and
an upper surface of the piezoelectric portion forms a flat surface with an upper surface of the thickness changing portion.

19. The bulk acoustic wave resonator of claim 18, wherein the thickness changing portion comprises an inclined portion disposed on the inclined surface of the insertion layer and an extended portion that extends outwardly from the inclined portion.
